(19) United States
(12) Patent Application Publication
(10) Pub. No.: US 2024/0145423 A1
(43) Pub. Date: May 2, 2024

(54) CONNECTION STRUCTURE, SEMICONDUCTOR DEVICE, AND INSULATION SUBSTRATE

(71) Applicants: DENSO CORPORATION, Kariya-city (JP); TOYOTA JIDOSHA KABUSHIKI KAISHA, Toyota-shi (JP); MIRISE Technologies Corporation, Nisshin-shi (JP)

(72) Inventor: TOMOHITO IWASHIGE, Nisshin-shi (JP)

(21) Appl. No.: 18/476,434

(22) Filed: Sep. 28, 2023

(30) Foreign Application Priority Data
Oct. 31, 2022 (JP) 2022-174870

(51) Int. Cl. H01L 23/00; H01L 23/36

(52) U.S. Cl. CPC H01L 24/32; H01L 23/36; H01L 24/29; H01L 2224/2919; H01L 2224/32245

(57) ABSTRACT

A connection structure includes: a first member; a second member arranged to oppose the first member and made of a material having a coefficient of linear expansion different from that of the first member; and a connection member that connects the first member and the second member with each other. The connection member includes a highly heat-resistant resin material, a carbon material made of carbon atom, and a void layer.

### CROSS REFERENCE TO RELATED APPLICATION

This application is based on Japanese Patent Application No. 2022-174870 filed on Oct. 31, 2022, the disclosure of which is incorporated herein by reference.

### TECHNICAL FIELD

The present disclosure relates to a connection structure, a semiconductor device, and an insulation substrate.

### BACKGROUND

A connection structure connects plural members having different linear expansion coefficients or elastic moduli, such as a metal member and a resin member.

### SUMMARY

According to an aspect of the present disclosure, a connection structure includes: a first member; a second member disposed to oppose the first member and made of a material having a linear expansion coefficient different from that of the first member; and a connection member that connects the first member and the second member. The connection member includes a heat-resistant resin material, a carbon material, and a void layer.

### BRIEF DESCRIPTION OF DRAWINGS

FIG. 1 is a sectional view illustrating a connection structure according to a first embodiment.

FIG. 2 is a view showing a cross section of the connection structure of the first embodiment using a scanning electron microscope (SEM).

FIG. 3 is a view showing a cross section of a connection member, using SEM, before being used for connection.

FIG. 4 is a diagram showing a relationship among a pressure of a connection member during pressurization, a thermal resistance of a connection structure, and an inclination angle of a carbon material.

FIG. 5 is a view showing a cross section of a connection structure using SEM under a pressure of 1 MPa.

FIG. 6 is a view showing a cross section of a connection structure using SEM under a pressure of 2 MPa.

FIG. 7 is a view showing a cross section of a connection structure using SEM under a pressure of 12.5 MPa.

FIG. 8 is a view showing a cross section of a connection member using SEM, corresponding to FIG. 3, in which a carbon material is natural graphite.

FIG. 9 is a view showing a cross section of a connection structure using SEM, corresponding to FIG. 2, in which a carbon material of a connection member is natural graphite.

FIG. 10 is a diagram showing a relationship among a pressure of a connection member during pressurization, an inclination angle of a carbon material, and a thermal resistance of the connection structure shown in FIG. 9.

FIG. 11 is a sectional view illustrating a connection structure according to a second embodiment.

FIG. 12 is an enlarged view showing XII region of FIG. 11.

FIG. 13 is an enlarged view showing a modification of the connection structure of the second embodiment, corresponding to FIG. 12.

FIG. 14 is a sectional view illustrating a connection structure according to a third embodiment.

FIG. 15 is an explanatory view for explaining a chemical bonding of a first member, a carbon material of a connection member, and a second member using an organic film.

FIG. 16 is a sectional view illustrating a connection structure according to a fourth embodiment.

FIG. 17 is a sectional view illustrating another arrangement example of a sealing member.

FIG. 18 is a sectional view illustrating a first modification of the connection structure of the fourth embodiment.

FIG. 19 is a sectional view illustrating a second modification of the connection structure of the fourth embodiment.

FIG. 20 is a sectional view illustrating a third modification of the connection structure of the fourth embodiment.

FIG. 21 is a sectional view illustrating a fourth modification of the connection structure of the fourth embodiment.

FIG. 22 is a sectional view illustrating a connection structure according to a fifth embodiment.

FIG. 23 is a sectional view showing a first modification of the connection structure of the fifth embodiment.

FIG. 24 is a top view illustrating an arrangement of sealing members in a second modification of the connection structure of the fifth embodiment.

FIG. 25 is a top view illustrating another arrangement of sealing members in the second modification of the fifth embodiment.

FIG. 26 is a top view illustrating another arrangement of sealing members in the second modification of the fifth embodiment.

FIG. 27 is a sectional view illustrating a connection structure according to a sixth embodiment.

FIG. 28 is a sectional view illustrating a first modification of the connection structure of the sixth embodiment.

FIG. 29 is a sectional view illustrating a second modification of the connection structure of the sixth embodiment.

FIG. 30 is a sectional view illustrating a semiconductor device using the connection structure according to an embodiment.

FIG. 31 is a sectional view illustrating an insulation substrate using the connection structure according to an embodiment.

FIG. 32 is an explanatory diagram illustrating an arrangement relationship between a connection member and a first member, which is a graphite heat dissipation plate.

### DETAILED DESCRIPTION

A connection structure connects plural members having different linear expansion coefficients or elastic moduli, such as a metal member and a resin member. At least one of the plural members is brought into contact with another heating element to enable heat dissipation. This type of connection structure is required to be connected at a low temperature or a normal temperature in order to reduce the influence of warpage or step. The plural members having different linear expansion coefficients are required to be connected with high thermal conductivity. Further, it is required to reduce the influence of deformation due to heat or stress. The connection member that connects the plural members having different linear expansion coefficients includes a bonding member such as solder and heat dissipation grease.

However, when solder is used, although the members can be connected to each other with high thermal conductivity, the members cannot be connected to each other at a low temperature or a normal temperature, and it is difficult to relax warpage or stress between the connected members. Further, in the case of heat dissipation grease, the members can be connected to each other at a low temperature or a normal temperature, but the members are not connected to each other with high thermal conductivity, and it is difficult to relax warpage and stress between the connected members.

A connection structure may include a connection member made of a thermoplastic resin material and a carbon-based material such as graphite having high thermal conductivity, and members are connected to each other at a low temperature or a normal temperature with high thermal conductivity.

However, when a part of the connection member is made of a thermoplastic resin material, the connection member is softened by heat of the heating element, and it is difficult to reduce deformation such as warpage or stress between the connected members.

A connection structure may include, for example, a semiconductor device having a connection member. The connection member connects an outer surface of a semiconductor module to a cooling body. A semiconductor element is resin-sealed in the semiconductor module. A connection structure may include, for example, an insulation substrate having a connection member that connects a conductive layer to an insulating layer. The conductive layer has a circuit wiring made of a metal material. The insulating layer is made of an insulating material. The insulation substrate is referred to a substrate in which a conductive layer is connected to one surface or both surfaces of an insulating layer.

The present disclosure provides a connection structure, a semiconductor device, and an insulation substrate in which members having different physical characteristics such as linear expansion coefficients can be connected to each other with high thermal conductivity at a low temperature or a normal temperature, and deformation and stress due to heat of a heating element can be relaxed.

According to an aspect of the present disclosure, a connection structure includes: a first member; a second member disposed to face the first member and made of a material having a linear expansion coefficient different from that of the first member; and a connection member that connects the first member and the second member. The connection member includes a highly heat-resistant resin material, a carbon material made of carbon atoms, and a void layer.

Accordingly, in the connection structure, the first member and the second member are thermally connected by the connection member including the highly heat-resistant resin material, the carbon material, and the void layer. In this connection structure, the first member and the second member are connected to each other by a carbon material having a high thermal conductivity at room temperature with a high thermal conductivity. Further, since the resin material of the connection material is a highly heat-resistant resin material, which is not softened by heat, deformation or stress due to heat of the heating element can be reduced.

According to an aspect of the present disclosure, a semiconductor device includes: a semiconductor module having a semiconductor element and a heat dissipation plate thermally connected to the semiconductor element; a heat dissipation body disposed to face the heat dissipation plate of the semiconductor module; and a connection member connecting the semiconductor element and the heat dissipation body. The connection member includes a highly heat-resistant resin material, a carbon material made of carbon atoms, and a void layer.

Accordingly, in the semiconductor device, the semiconductor module and the heat dissipation body are thermally connected to each other by the connection member including the highly heat-resistant resin material, the carbon material, and the void layer. The semiconductor module and the heat dissipation body are thermally connected by the carbon material of the connection member having high thermal conductivity, and the connection member is not softened by heat, due to the resin material which is a highly heat-resistant resin material. Therefore, in the semiconductor device, the semiconductor module and the heat dissipation body are connected to each other with high thermal conductivity at room temperature, and deformation or stress due to heat of the semiconductor element, which is a heating element, can be reduced.

According to an aspect of the present disclosure, an insulation substrate includes: a conductive layer made of a conductive material; an insulating layer disposed to face the conductive layer and made of an insulating material; and a connection member that connects the conductive layer and the insulating layer. The connection member includes a highly heat-resistant resin material, a carbon material made of carbon atoms, and a void layer.

Accordingly, the conductive layer and the insulating layer are thermally connected to each other by the connection member including the highly heat-resistant resin material, the carbon material, and the void layer. The conductive layer and the insulating layer are thermally connected by the carbon material of the connection member having high thermal conductivity. Since the resin material is a highly heat-resistant resin material, the connection member is not softened by heat. Therefore, the conductive layer and the insulating layer are connected to each other with high thermal conductivity at room temperature, and the deformation and stress due to heat of other heating elements can be reduced.

Hereinafter, embodiments of the present disclosure will be described with reference to the drawings. In the following embodiments, the same reference numerals are assigned to portions that are the same or equivalent to each other for description.

### First Embodiment

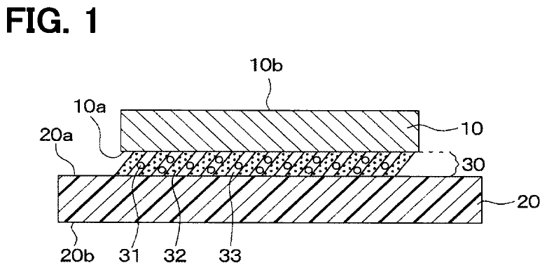

A first embodiment will be described with reference to the drawings. In FIG. 1, a connection member 30, which will be described later, is shown schematically for easy understanding.

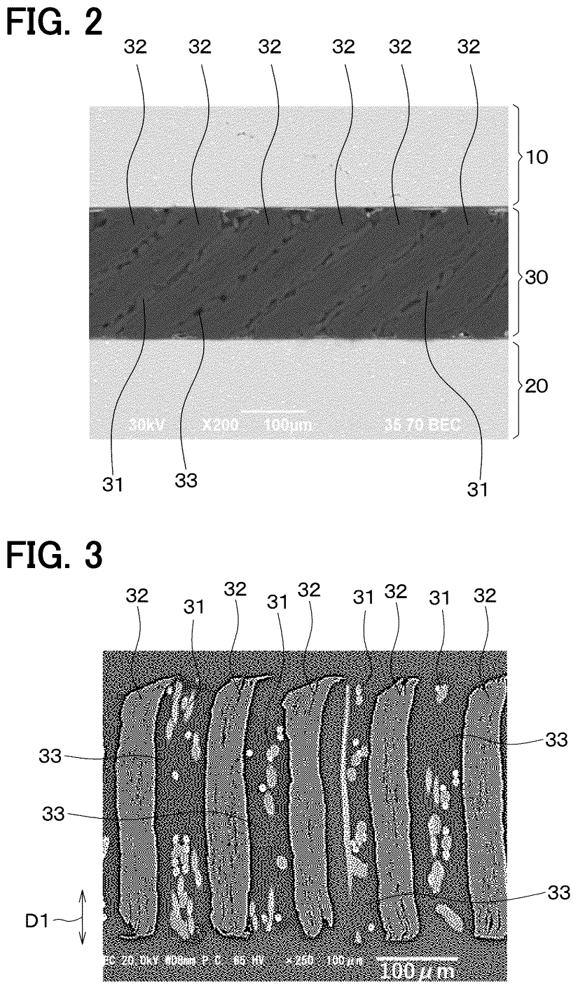

As illustrated in FIG. 1, a connection structure according to the present embodiment includes a first member 10, a second member 20, and the connection member 30 disposed between the first member 10 and the second member 20 to thermally connect the first member 10 and the second member 20. Due to this connection structure, it is suitable, for example, the first member 10 is connected to another heating element such as an electronic component so as to diffuse the heat of the heating element from the first member 10 to the second member 20 via the connection member 30. In this connection structure, for example, as shown in FIG. 2, a carbon material 32 (described later) of the connection member 30 is inclined with respect to the thickness direction, and the first member 10 and the second member 20 are connected with high thermal conductivity via the carbon material 32.

For example, at least a part of the first member 10 in contact with the connection member 30 is made of a highly thermally conductive material having high thermal conductivity such as a metal material. Examples of the first member 10 include, but are not limited to, a metal plate, an insulating built-in substrate in which metal layers are bonded to both surfaces of an insulating substrate, and a semiconductor module in which a semiconductor element is connected to a heat sink and sealed with resin.

The second member 20 is an arbitrary member made of a material having a linear expansion coefficient and an elastic modulus different from at least the first member 10. When the first member 10 is a composite member constructed of plural materials, the second member 20 has a linear expansion coefficient and an elastic modulus different from those of the first member 10 as a whole. In such a case, for example, the first member 10 is a composite member and a part of the first member 10 facing the second member 20 is made of the same material as the second member 20, but the other part of the first member 10 includes a material having a linear expansion coefficient and elastic modulus different from those of the second member 20. The second member 20 is disposed to face the first member 10 and is thermally connected to the first member 10 via the connection member 30. The second member 20 is, for example, an insulating substrate made of ceramic or the like, a heat dissipation plate or a cooler made of a metal material having high thermal conductivity such as Al (aluminum) or an alloy material thereof, or the like, but is not limited thereto. The second member 20 has, for example, a planar size larger than that of the first member 10, and is disposed to overlap the entire region of the first member 10 inside the outer shell.

As shown in FIG. 1, the connection member 30 includes a high heat-resistant resin material 31, a carbon material 32, and a void layer 33. The carbon material 32 thermally connects the first member 10 and the second member 20. In the connection member 30, for example, plural carbon materials 32 are regularly arranged with gaps therebetween. The high heat-resistant resin material 31 is partially arranged in the gap, and the remaining part of the gap is the void layer 33. The connection member 30 is disposed, for example, between the first member 10 and the second member 20, and is pressed by the first member 10 and the second member 20 at room temperature or a low temperature lower than or equal to 150° C., so that the carbon material 32 having a high thermal conductivity comes into contact with each of the first member 10 and the second member 20, for heat conduction between the first member 10 and the second member 20. As shown in FIG. 3, for example, before the thermal connection between the first member 10 and the second member 20, the carbon material 32 is disposed to extend along the thickness direction D1 of the connection member 30, and the width of the void layer 33 is wider than that at the time of thermal connection. The connection member 30 has flexibility, and the carbon materials 32 are inclined substantially uniformly with respect to the thickness direction D1 when the first member 10 and the second member 20 are thermally connected to each other. The inclination angle of the carbon material 32 will be described later.

The connection member 30 is obtained, for example, by preparing a graphite sheet in which flaky graphite is regularly arranged, applying a material constituting the high heat-resistant resin material 31 or a solution containing the material to the graphite sheet, and then heating the surface to which the solution is applied in a pressurized state. The graphite sheet is obtained, for example, by pressurizing powdery or flaky graphite at 1 MPa or more to form a sheet, drying the obtained sheet-like graphite by an arbitrary method such as decompression or natural drying, and then pressurizing and heating in a range of 100° C. to 400° C. and 10 MPa to 40 MPa. In addition to the high heat-resistant resin material 31 and the carbon material 32, the connection member 30 may contain other materials such as metal particles and spacers to the extent that flexibility is not impaired, as necessary. The thickness of the connection member 30 is, for example, about 100 μm to 1 mm in a state where the first member 10 and the second member 20 are thermally connected to each other, but is not limited to this range. In addition, the connection member 30 is not limited to one in which the carbon materials 32 are regularly arranged in a predetermined pattern such as a staggered pattern, and may have a configuration in which some or all of the carbon materials 32 are irregularly arranged.

The high heat-resistant resin material 31 functions as a binder for the carbon materials 32 regularly arranged at a distance. The high heat-resistant resin material 31 is a thermosetting resin material, or/and a thermoplastic resin material having a melting point of 200° C. or higher. The high heat-resistant resin material 31 is, for example, a thermosetting resin having flexibility in a cured state, such as a flexible epoxy resin, a rubber-based resin, a urethane-based resin, a silicone-based resin, a fluorine-based resin, and an acrylic resin, but is not limited thereto. The high heat-resistant resin material 31 is a thermoplastic resin, for example, polyester such as polyethylene terephthalate having a melting point of 200° C. or higher, but is not limited thereto. Since the high heat-resistant resin material 31 serves as a binder, the connection member 30 is restricted from being excessively softened in a heated state while securing flexibility.

The carbon material 32 is in contact with each of the first member 10 and the second member 20, and thermally connects the first member 10 and the second member 20 at a high thermal conductivity equal to or higher than a predetermined value. The carbon material 32 is formed of a material made of carbon atoms, such as artificial graphite (thermal conductivity: about 1700 W/(m·K)), natural graphite (thermal conductivity: about 400 to 500 W/(m·K)), or carbon nanotubes (theoretical value of thermal conductivity: about 6000 W/(m·K)). The carbon material 32 is exposed to the outside at the contact surface with the first member 10 and the contact surface with the second member 20 of the connection member 30. For example, when viewed from the normal direction to the contact surface of the connection member 30, the carbon materials 32 are arranged along one direction of the contact surface and are arranged with a gap in a direction orthogonal to the one direction. Hereinafter, for convenience of description, one direction on the contact surface of the connection member 30 may be referred to as a surface direction, and a direction orthogonal to the surface direction may be referred to as an arrangement direction. One end of the carbon material 32 is in contact with the first member 10, and the other end opposite to the one end is in contact with the second member 20, while being inclined substantially uniformly along the arrangement direction, since the connection member 30 is pressed between the first member 10 and the second member 20. The thermal conductivity of the entire connection member 30 is, for example, about 800 W/(m·K) when the carbon material 32 is artificial graphite and about 250 W/(m·K) when the carbon material 32 is natural graphite, but is not limited thereto.

The void layer 33 is a gap between the carbon materials 32 adjacent to each other along the arrangement direction. The void layer 33 plays a role of securing cushioning properties when the connection member 30 is pressed by the first member 10 and the second member 20.

The above is the basic configuration of the connection structure according to the present embodiment. This connection structure is preferably applied to, for example, a semiconductor device in which a semiconductor module and a cooler are connected by the connection member 30, an insulation built-in substrate in which a conductive layer or a graphite heat dissipation plate is connected to a ceramic substrate by the connection member 30, or the like, but can be applied to other applications.

Next, the relationship between the pressure applied to the connection member 30 by the first member 10 and the second member 20, the thermal resistance of the connection structure obtained thereby, and the inclination angle of the carbon material 32 will be described.

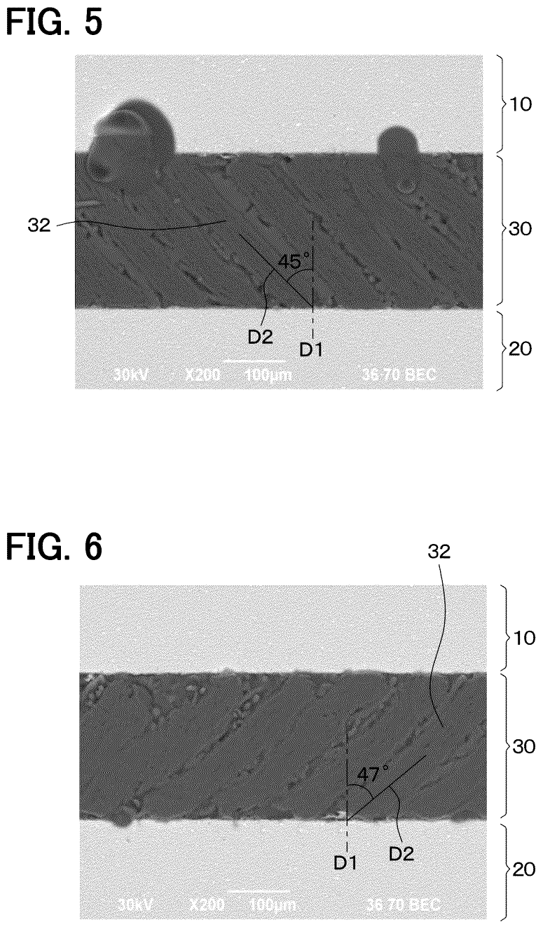

Hereinafter, for convenience of description, for example, as shown in FIG. 5 to FIG. 7, a direction along a straight line connecting one end of the carbon material 32 in contact with the first member 10 and the other end of the carbon material 32 in contact with the second member 20 is referred to as a heat conduction direction D2. The inclination angle of the carbon material 32 means an angle formed by the thickness direction D1 of the connection member 30 and the heat conduction direction D2. The thickness direction D1 can also be said to be a direction along a normal direction to the contact surface 10a of the first member 10 with the connection member 30 or the contact surface 20a of the second member 20 with the connection member 30.

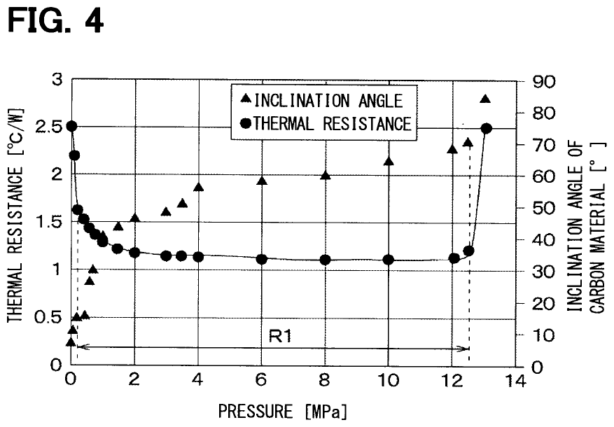

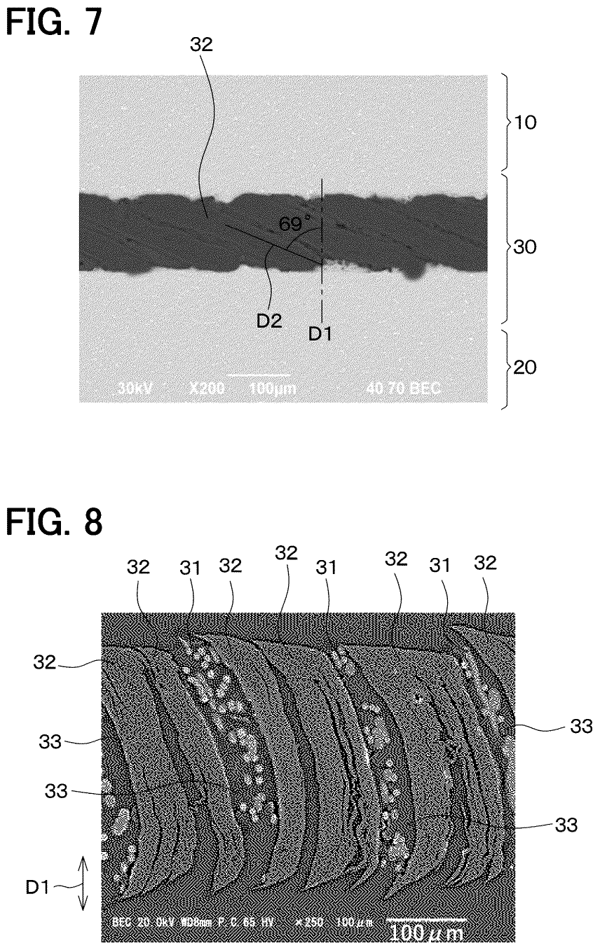

According to intensive studies by the present inventors, for example, as shown in FIG. 4, the inclination angle of the carbon material 32 changes according to the pressure when the connection member 30 is pressurized at room temperature or a low temperature lower than or equal to 150° C., and the thermal resistance of the connection structure changes according to the inclination angle. Specifically, when the pressure of the carbon material 32 is 1 MPa, for example, as shown in FIG. 5, the inclination angle of the carbon material 32 is 45°. When the pressure is 2 MPa, for example, as shown in FIG. 6, the inclination angle of the carbon material 32 is 47°. When the pressure is 12.5 MPa, for example, as shown in FIG. 7, the inclination angle of the carbon material 32 is 69°. As a result of further examination, in the connection structure, when the inclination angle of the carbon material 32 is within a range R1 more than or equal to 14° and lower than or equal to 70°, the thermal resistance is reduced to be lower than or equal to 1.6° C./W. When the inclination angle is outside the range R1, the thermal resistance exceeds 2.2° C./W. That is, in the connection member 30, when the inclination angle of the carbon material 32 is in the range of 14° or more and 70° or less, the one end of the carbon material 32 and the first member 10 are in good contact with each other and the other end of the carbon material 32 and the second member 20 are in good contact with each other. Thus, the first member 10 and the second member 20 can be thermally connected with high thermal conductivity.

When the inclination angle of the carbon material 32 is less than 14°, it is considered that the contact between the carbon material 32 of the connection member 30 and the first member 10 and the second member 20 becomes insufficient due to insufficient pressure, such that the thermal resistance does not decrease. When the inclination angle of the carbon material 32 exceeds 70°, it is considered that the thermal resistance does not decrease due to excessive inclination of the carbon material 32 of the connection member 30 with respect to the direction in which the first member 10 and the second member 20 are connected or damage of the carbon material 32 itself due to excessive pressure. In addition, when the inclination angle of the carbon material 32 exceeds 70°, it is also considered that the ratio of the carbon material 32 in which both ends are not in contact with the first member 10 and the second member 20, that is, the non-contact region between the carbon material 32 and the members 10, 20 increases, such that the thermal resistance does not decrease.

The inclination angle of the carbon material 32 can be calculated from the difference between the thickness of the connection member 30 before the pressurization and the thickness after the pressurization. For example, when the thickness of the connection member 30 before pressurization is 300 μm, the thickness of the carbon material 32 before inclination can be regarded as 300 μm. When the thickness of the connection member 30 after pressurization is 200 μm, the carbon material 32 having a thickness of 300 μm collapses without being deformed, and the inclination angle at which the height from one end to the other end of the carbon material 32 is 200 μm is defined as θ, the inclination angle θ can be calculated by a trigonometric function. The inclination angles at pressures of 1 MPa, 2 MPa, and 12.5 MPa shown in FIGS. 5 to 7 coincided with the numerical values obtained by the calculation method described above.

FIGS. 4 to 7 correspond to the connection structure using the connection member 30 in which the carbon material 32 is artificial graphite (hereinafter, referred to as first connection structure), but the same tendency is observed also in case where the carbon material 32 is natural graphite. Hereinafter, for simplification of description, the connection structure using the connection member 30 in which the carbon material 32 is natural graphite is referred to as a second connection structure.

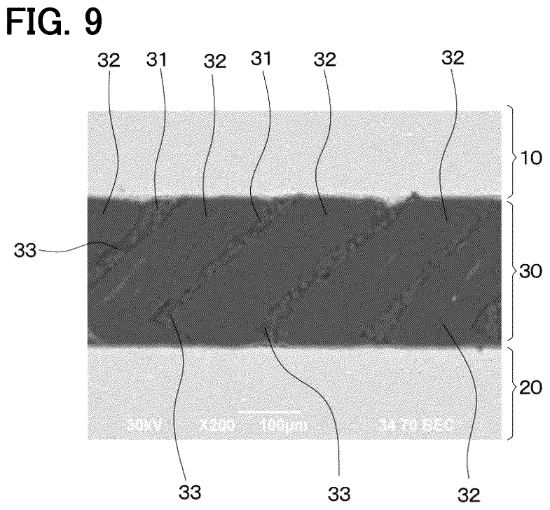

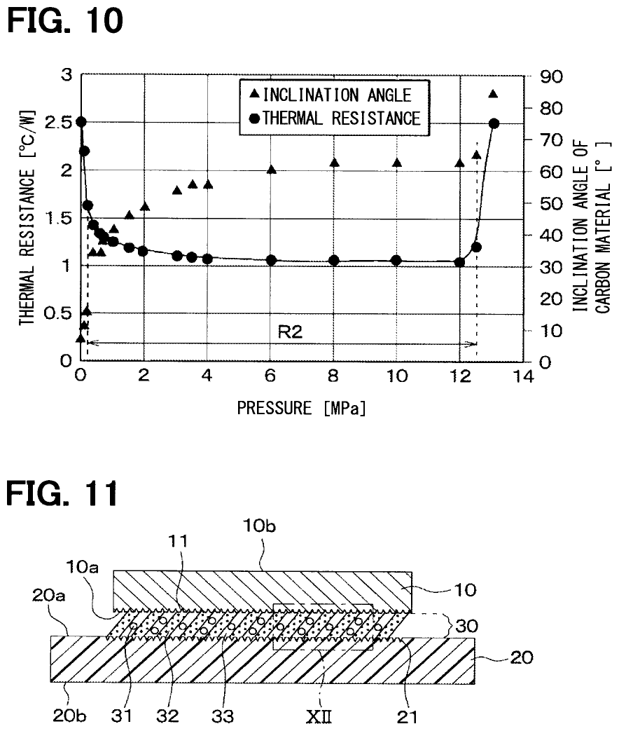

In the connection member 30, the carbon material 32 is natural graphite, and a void different from the void layer 33 is generated in one carbon material 32, as shown in FIG. 8, before the first member 10 and the second member 20 are connected. However, in the second connection structure, for example, as shown in FIG. 9, similarly to the first connection structure, the carbon materials 32 are inclined substantially uniformly, and the voids in one carbon material 32 are almost closed. In the second connection structure, the relationship between the pressure at the time of pressurization of the connection member 30, the thermal resistance, and the inclination angle of the carbon material 32 show the same tendency as in the first connection structure. In the second connection structure, for example, as shown in FIG. 10, when the inclination angle of the carbon material 32 is within a range R2 larger than or equal to 14° and smaller than or equal to 70°, the thermal resistance is reduced to be lower than or equal to 1.6° C./W. When the inclination angle is outside the range R2, the thermal resistance exceeds 2.2° C./W. This result suggests that even when the material used for the carbon material 32 is changed, by pressurizing the connection member 30 so that the inclination angle of the carbon material 32 is within a predetermined range, it is possible to connect two members having different physical properties such as a linear expansion coefficient with high thermal conductivity.

According to the present embodiment, a connection structure thermally connects the first member 10 and the second member 20 having different physical characteristics such as linear expansion coefficients via the carbon material 32 of the connection member 30 including the high heat-resistant resin material 31, the carbon material 32, and the void layer 33. For this connection structure, a step of connecting at a high temperature exceeding 150° C. is unnecessary, since the connection member 30 is pressed by the first member 10 and the second member 20 at room temperature or a low temperature lower than or equal to 150° C., and each of the first member 10 and the second member 20 is brought into contact with the carbon material 32 with high conductivity. In addition, in this connection structure, since the first member 10 and the second member 20 are thermally connected by the carbon material 32, without a joining material such as solder, deformation and stress due to heat caused by an external heating element are alleviated. Further, since the binder between the carbon materials 32 is the high heat-resistant resin material 31, the connection member 30 is not excessively softened by heat. Therefore, in this connection structure, the first member 10 and the second member 20 are connected to each other with high thermal conductivity at room temperature or low temperature by the carbon material 32 having high thermal conductivity, and the connection member 30 is not softened by heat such that deformation or stress due to heat of an external heating element can be relaxed.

(1) Since one end of the carbon material 32 is in contact with the first member 10 and the other end opposite to the one end is in contact with the second member 20, the first member 10 and the second member 20 are thermally connected by the carbon material 32 having high thermal conductivity, such that the thermal resistance of the connection structure can be reduced.

(2) By setting the inclination angle of the carbon material 32 in the range of 14° or more and 70° or less, the connection member 30 can ensure contact between the carbon material 32 and the first member 10 and the second member 20, such that the first member 10 and the second member 20 can be connected with high thermal conductivity.

### Second Embodiment

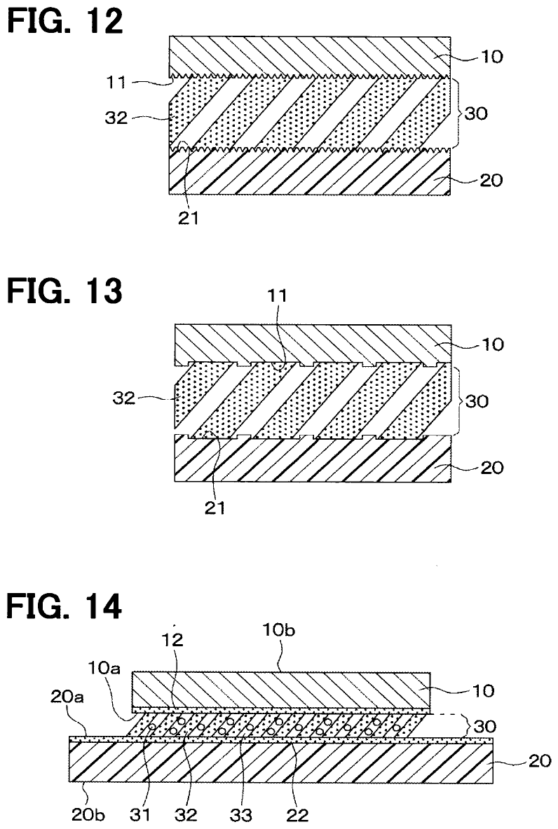

A second embodiment will be described with reference to the drawings. In FIGS. 12 and 13, the high heat-resistant resin material 31 of the connection member 30 is omitted for easy understanding.

The connection structure of the present embodiment is different from that of the first embodiment in that, for example, as shown in FIG. 11, recesses 11 are formed on the contact surface 10a of the first member 10 and recesses 21 are formed on the contact surface 20a of the second member 20. These differences will be mainly described in the present embodiment.

The first member 10 according to the present embodiment, for example, as illustrated in FIG. 12, has the recesses 11 formed in the contact surface 10a. The recesses 11 are formed in order to increase the frictional force relative to the carbon material 32 of the connection member 30 to make contact with the carbon material 32 easier. The recess 11 is formed to have a width smaller than the width of one carbon material 32 and to have a depth of a micrometer order or less by any method such as laser light irradiation or machining such as grinding or cutting. That is, the contact surface 10a is a roughened surface having a fine uneven structure in which a protrusion between the recesses 11 and the recess 11 are alternately formed.

In the present embodiment, the recesses 21 are formed on the contact surface 20a of the second member 20. Similarly to the recesses 11, the recesses 21 are formed in order to increase a frictional force with the carbon material 32, and the recess 21 is made to have a width and a depth equivalent to those of the recess 11 by, for example, the above-described arbitrary method. That is, the contact surface 20a is, for example, a roughened surface having fine irregularities of the order of micrometers, similarly to the contact surface 10a.

As illustrated in FIG. 13, each of the recesses 11, 21 may have a groove shape that is larger than the width of the carbon material 32 and into which an end portion of the carbon material 32 enters. Even in this case, the carbon material 32 is more likely to come into contact with each of the first member 10 and the second member 20 by pressurization, compared with a case where the contact surface 10a, 20a is a smooth surface. The width, the depth, the arrangement pattern, the arrangement interval, and the like, in the case where the recesses 11, 21 are formed in a groove shape, can be appropriately changed according to the width, the arrangement pattern, and the like of the carbon material 32. That is, the contact surface 10a, 20a may have any configuration while the carbon material 32 does not easily slip. For example, the contact surface 10a, 20a may have recesses of a predetermined pattern according to the arrangement of the carbon material 32, in addition to the roughened surface having fine irregularities.

The present embodiment also provides a connection structure with the same effects as those of the first embodiment. The connection structure of the present embodiment also provides the following effects.

(1) Due to the recesses 11 on the contact surface 10a of the first member 10 and the recesses 21 on the contact surface 20a of the second member 20, the first member 10 and the second member 20 are in contact with the carbon material 32 at a pressure lower than that in the first embodiment. Therefore, this connection structure has an effect of further stabilizing the contact state between the first member 10 and the second member 20 and the carbon material 32.

### Third Embodiment

A third embodiment will be described with reference to the drawings. In FIG. 14, the thickness of an organic film 12, 22, which will be described later, is exaggerated for easy understanding of the configuration.

The connection structure of the present embodiment is different from that of the first embodiment in that the organic film 12 is interposed between the connection member 30 and the first member 10, and the organic film 22 is interposed between the connection member 30 and the second member 20. This different point will be mainly described in the present embodiment.

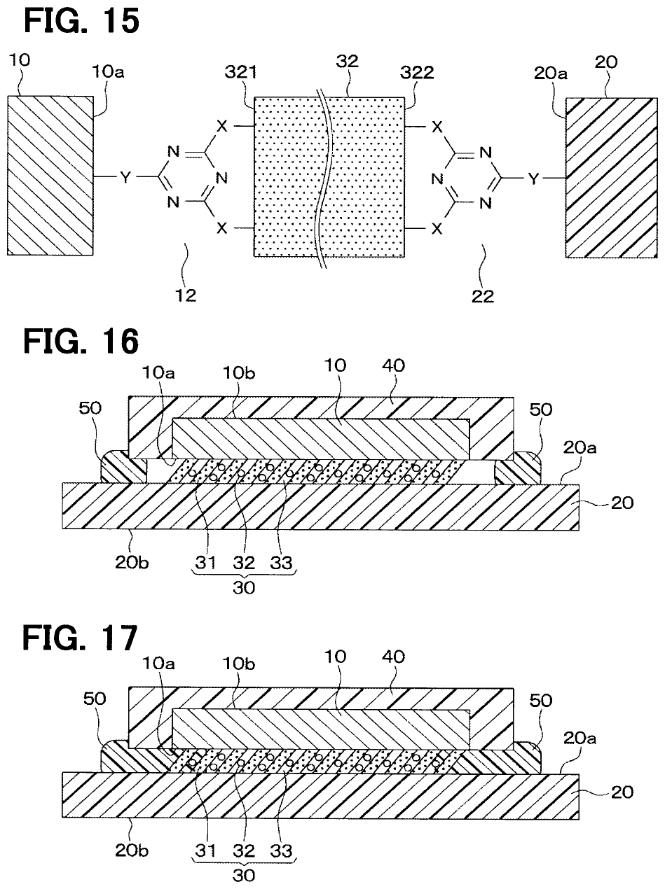

In the present embodiment, the organic film 12 is formed on the contact surface 10a of the first member 10. The organic film 12 is made of an arbitrary organic material bonded to each of the constituent material of the first member 10 and the carbon material 32 of the connection member 30. For example, as illustrated in FIG. 15, the organic film 12 is formed of a triazine-based compound having a triazine ring used for a silane coupling agent or the like. The constituent material of the organic film 12 illustrated in FIG. 15 is, for example, a functional group in which the X group has an amino group at a terminal or an azi group, and a functional group in which the Y group has a silanol group at a terminal. The same applies to the organic film 22. As the constituent material of the organic film 12, 22, for example, a reactivity imparting compound described in JP 2020-143007 A, a triazine-based compound described in JP 2021-130839 A, or the like can be used, but other known triazine-based compounds may be used. For example, in a case where the first member 10 is formed of a metal material such as Cu (copper), the organic film 12 is applied to the contact surface 10a so that the amino group interacts with and chemically bonds to the first member 10. In FIG. 14, for the sake of convenience, the organic film 12 is illustrated as a uniform film having a predetermined thickness. However, actually, the organic film 12 is, for example, one molecular layer, and is configured not to inhibit a reduction in thermal resistance due to contact between the first member 10 and the carbon material 32. The same applies to the organic film 22.

For example, in the present embodiment, the connection member 30 is subjected to surface treatment on both surfaces facing the first member 10 and the second member 20, and is chemically bonded to the organic film 12, 22. For example, the connection member 30 has an upper surface from which one end 321 of the carbon material 32 facing the first member 10 is exposed, and a lower surface from which the other end 322 of the carbon material 32 facing the second member 20 is exposed. Examples of the optional surface treatment include, but are not limited to, corona discharge, atmospheric pressure plasma, ozone oxidation, superheated steam, and the like. As a result, a carboxyl group or an oxygen atom (not shown) to be chemically bonded to the organic film 12, 22 is introduced to the surface of the one end 321 and the other end 322 of the carbon material 32. The carboxyl group or the oxygen atom (not shown) at the one end 321 and the other end 322 of the carbon material 32 is chemically bonded to the amino group of the organic film 12.

In the present embodiment, the organic film 22 is formed on the contact surface 20a of the second member 20. The organic film 22 is formed of an arbitrary organic material bonded to each of the constituent material of the second member 20 and the carbon material 32 of the connection member 30. The organic film 22 is formed by being applied to the contact surface 20a of the second member 20, for example, similarly to the organic film 12. For example, when the contact surface 20a is formed of Al, the second member 20 is subjected to an arbitrary surface treatment in the same manner as the connection member 30, and a hydroxyl group (not illustrated) is introduced into the contact surface 20a. The second member 20 is chemically bonded to the organic film 22 by, for example, dehydration condensation of a hydroxyl group (not shown) of the contact surface 20a and a silanol group of the organic film 22. The bonding of the organic film 12, 22, the first member 10, the second member 20, and the carbon material 32 can also be referred to as molecular bonding.

The present embodiment also provides a connection structure with the same effects as those of the first embodiment. The connection structure of the present embodiment also provides the following effects.

(1) The organic film 12 is provided on the contact surface 10a of the first member 10, and the organic film 22 is provided on the contact surface 20a of the second member 20. When the organic film 12, 22 joins the first member 10 and the second member 20 to the carbon material 32, the interface therebetween is in the chemically bonded state. For this reason, the first member 10, the carbon material 32, and the second member 20 are firmly connected to each other, and an effect of further stabilizing the contact at the interface therebetween is obtained. In addition, since the organic film 12, 22 is a single molecular layer, it is possible to suppress an increase in thermal resistance at the interface between the carbon material 32 and the first member 10 and the second member 20.

### Fourth Embodiment

A fourth embodiment will be described with reference to the drawings.

The connection structure of the present embodiment is different from that of the first embodiment in that, for example, as shown in FIG. 16, the connection structure includes a third member 40 surrounding the outer periphery of the first member 10 and a sealing member 50 connecting the second member 20 and the third member 40. This different point will be mainly described in the present embodiment.

The third member 40 has a shape, for example, surrounding a part or whole of the side surface of the first member 10 and is arranged to face the second member 20 together with the first member 10. The third member 40 covers, for example, the back surface 10b of the first member 10 opposite to the contact surface 10a. The third member 40 has, for example, a planar size larger than that of the first member 10 but smaller than that of the second member 20. The third member 40 is bonded to the second member 20 by, for example, the sealing member 50 surrounding the entire periphery of the side surface. The third member 40 can be made of, for example, a resin material, a metal material, a composite material thereof, or any other material.

The sealing member 50 bonds and holds the second member 20 and the third member 40. The sealing member 50 is made of, for example, an arbitrary resin material having adhesiveness such as an epoxy resin or an acrylic resin. For example, the sealing member 50 is arranged so as to surround the side surface of the third member 40 in a continuous frame shape in a top view, that is, when viewed from a normal direction to the contact surface 20a. For example, the sealing member 50 is disposed by application or the like in a state where the connection member 30 is pressurized by the first member 10, the third member 40, and the second member 20, but may be disposed before pressurization. In other words, the sealing member 50 adhesively holds the second member 20 and the third member 40 to maintain a state in which the connection member 30 is pressurized by the first member 10 and the second member 20, so as to ensure the thermal connection. The sealing member 50 seals a gap region between the first member 10 and the third member 40 and the second member 20. Thus, even when dust is generated due to the carbon material 32, the sealing member 50 serves to confine the generated dust in the sealed space.

For example, as illustrated in FIG. 17, the sealing member 50 may flow into the gap between the first member 10 and the second member 20, and a part thereof may enter the void layer 33. When the connection member 30 is disposed in a state of being pressed by the first member 10 and the second member 20, the sealing member 50 does not enter between the carbon material 32 and the first member 10 or the second member 20, and does not inhibit heat conduction between the first member 10 and the second member 20. In addition, in the present connection structure, since the contact area between the connection member 30 and the first member 10 and the second member 20 is sufficiently larger than the bonding area by the sealing member 50, the effect of alleviating deformation and stress due to the difference in the linear expansion coefficient of the first member 10 and the second member 20 is not impaired.

The present embodiment also provides a connection structure with the same effects as those of the first embodiment. The connection structure of the present embodiment also provides the following effects.

(1) In this connection structure, the third member 40 surrounding the outer periphery of the first member 10 and the second member 20 are bonded to each other by the sealing member 50, so that the pressurized state of the connection member 30 by the first member 10 and the second member 20 is maintained. For this reason, the contact between the first member 10 and the second member 20 and the carbon material 32 is maintained in a stable state, and the connection between the first member 10 and the second member 20 with high thermal conductivity can be ensured more continuously. In addition, since the space in which the connection member 30 is disposed is sealed by the sealing member 50, even when dust is generated due to the carbon material 32, it is possible to restrict the generated dust from being diffused to the outside.

### Modification of Fourth Embodiment

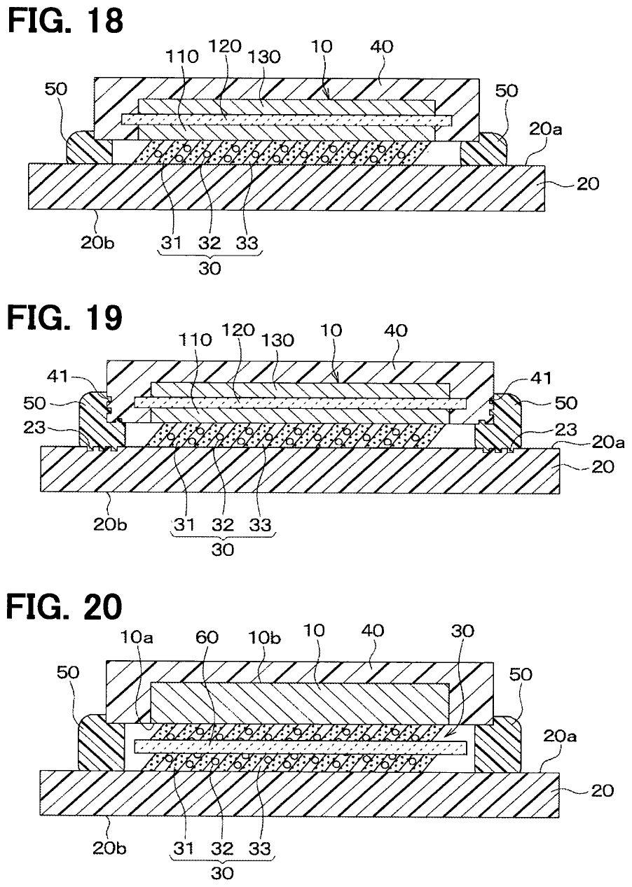

In the connection structure of the fourth embodiment, for example, as illustrated in FIG. 18, the first member 10 may be a stacked body in which a heat dissipation plate 110, an insulating substrate 120, and a metal layer 130 are stacked in this order. In this case, for example, the first member 10 may be a direct bonded copper (DBC) substrate in which the heat dissipation plate 110 and the metal layer 130 are made of Cu and the insulating substrate 120 is made of a ceramic substrate.

In addition, in the connection structure of the fourth embodiment, for example, as illustrated in FIG. 19, a high adhesion portion 23, 41 is formed at a part of the second member 20 and the third member 40 that comes into contact with the sealing member 50. The sealing member 50 enters recesses, grooves, or the like in the high adhesion portion 23, 41. The high adhesion portion 23 is formed on the second member 20 by an arbitrary method such as laser light irradiation or machining, and a part of the sealing member 50 enters the high adhesion portion 23 to cause an anchor effect, so that the adhesion with the sealing member 50 is enhanced more than other portions. The high adhesion portion 41 is formed on the third member 40 by an arbitrary method and plays the same role as the high adhesion portion 23. The high adhesion portion 23, 41 only needs to improve adhesion to the sealing member 50, and the pattern and the like thereof may be appropriately changed. FIG. 19 illustrates an example in which the first member 10 is a composite member, but in the present modification, the first member 10 may be a single member. Further, this connection structure may be configured such that only one of the second member 20 and the third member 40 has the high adhesion portion 23, 41.

In the connection structure of the fourth embodiment, for example, as illustrated in FIG. 20, the fourth member 60 may be disposed between the first member 10 and the second member 20. The connection member 30 may be disposed between the first member 10 and the fourth member 60 and between the second member 20 and the fourth member 60. In this case, the fourth member 60 is made of, for example, any material having high thermal conductivity such as ceramic.

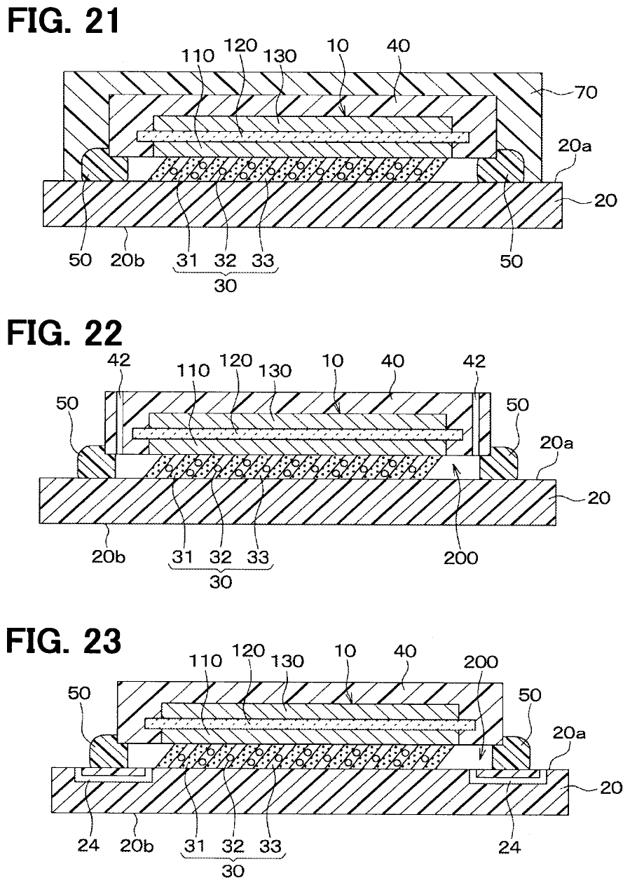

For example, as shown in FIG. 21, the connection structure of the fourth embodiment may further include a fifth member 70 that covers the entire area of the bonding region between the second member 20 and the third member 40, and the third member 40 may be sealed by the fifth member 70. The fifth member 70 is made of, for example, an arbitrary resin material. In the connection structure of the present modification, the connection portion between the first member 10 and the second member 20 via the connection member 30 is double-sealed by the third member 40 and the fifth member 70. Therefore, an effect of further stabilizing the contact between the first member 10 and the second member 20 and the carbon material 32 can be obtained.

Effects similar to those of the fourth embodiment can also be obtained by the modification.

### Fifth Embodiment

A fifth embodiment will be described with reference to the drawings.

The connection structure of the present embodiment is different from that of the fourth embodiment in that a communication portion 42 is formed in the third member 40 as shown in FIG. 22. This different point will be mainly described in the present embodiment.

Hereinafter, for convenience of description, a space surrounded by the first member 10 and the third member 40, the second member 20, and the sealing member 50 is referred to as an internal space 200. The internal space 200 can house the connection member 30.

In the present embodiment, the third member 40 has the communication portion 42 that communicates the internal space 200 with the external space. The communication portion 42 is, for example, a through hole formed along the thickness direction of the third member 40, and is formed by drilling or the like. The communication portion 42 functions as a passage when a fluid such as air in the internal space 200 is expanded by heat from an external heating element, and suppresses an increase in the internal pressure of the internal space 200. The number, dimensions, shape, arrangement, and the like of the communication portions 42 may be appropriately changed while the fluid in the internal space 200 can pass through the communication portions.

According to the present embodiment, the same effects as those of the fourth embodiment can be obtained. The connection structure of the present embodiment also provides the following effects.

(1) Since the communication portion 42 is formed in the third member 40, even when the fluid in the internal space 200 expands due to heat, the fluid can be released to the outside through the communication portion 42, and an increase in the internal pressure can be suppressed.

### Modification of Fifth Embodiment

As shown in FIG. 23, in the connection structure of the fifth embodiment, a communication portion 24 is formed in the second member 20 to communicate the internal space 200 with the external space, instead of the third member 40. Similarly to the communication portion 42, the communication portion 24 is formed by an arbitrary method, and the number, shape, size, arrangement, and the like thereof can be appropriately changed while it is possible to connect the internal space 200 and the external space and allow a fluid to pass therethrough.

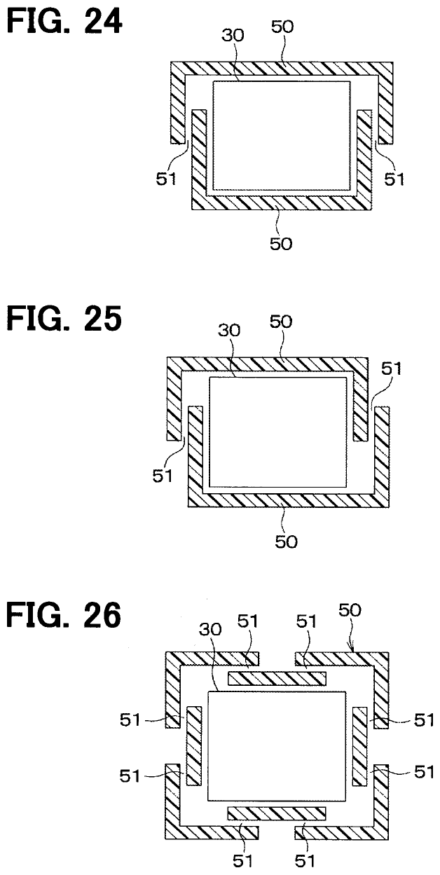

In addition, for example, as illustrated in FIG. 24, the connection structure of the fifth embodiment may be configured such that the sealing member 50 is divided into plural pieces, such that a gap is generated between the sealing members 50, and the gap functions as the communication portion 51. In this case, the second member 20 and the third member 40 do not need to have a communication portion.

In FIG. 24, in order to facilitate understanding of the arrangement example of the sealing member 50, the sealing member 50 is hatched although this is not a cross section. FIG. 24 shows an upper surface layout as viewed from the normal direction to the contact surface 20a of the second member 20 (not shown in FIG. 24). The same applies to FIGS. 25 and 26.

For example, as illustrated in FIG. 24, the sealing member 50 may be divided into two substantially U-shaped patterns, and a small substantially U-shaped pattern enters the inside of a large substantially U-shaped pattern in the opposite orientation. In this case, the gap between the two substantially U-shaped patterns functions as the communication portion 51. For example, as illustrated in FIG. 25, the sealing member 50 may be divided and arranged in two substantially U-shaped patterns having substantially the same size, and the two patterns may be alternately arranged at the opposite orientations. In addition, for example, as illustrated in FIG. 26, the sealing member 50 may be arranged to have four substantially L-shaped patterns arranged apart from each other so as to form four corners, and four linear patterns arranged inside the four substantially L-shaped patterns. In this case, each of the linear patterns is longer than the gap between adjacent substantially L-shaped patterns, and is disposed so as to be adjacent to the entire area of the gap. In this case, the gap between the linear pattern and the substantially L-shaped pattern functions as the communication portion 51. The pattern shape in which the sealing member 50 is divided and arranged is not limited to the example described above, and may be appropriately changed.

According to the modifications, the same effects as those of the fifth embodiment can be obtained.

### Sixth Embodiment

A sixth embodiment will be described with reference to the drawings.

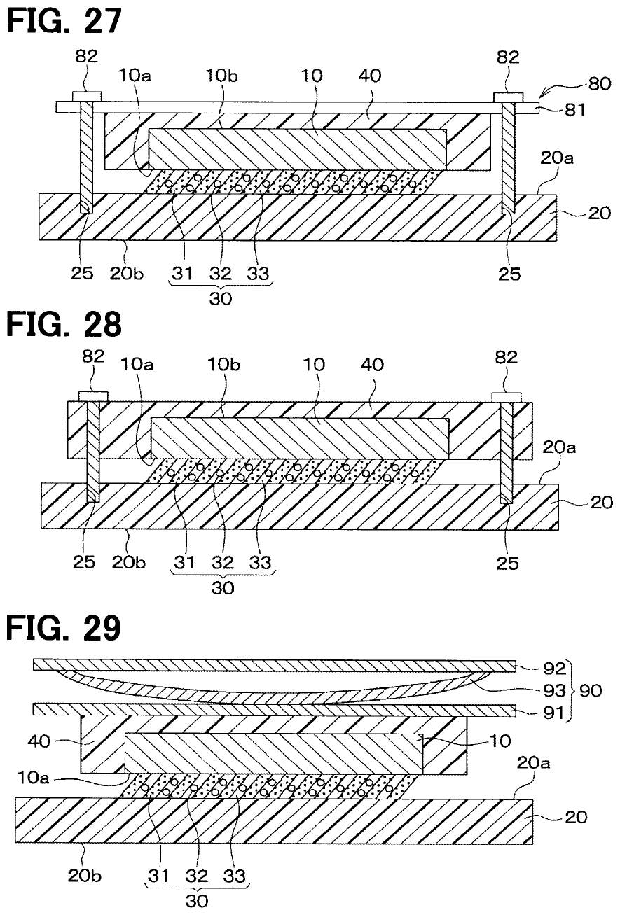

For example, as shown in FIG. 27, the connection structure of the present embodiment is different from that of the first embodiment in that the connection structure further includes a fastening member 80 disposed in contact with the surface of the third member 40 opposite to the exposed side of the first member 10. The fastening member 80 presses the first member 10 toward the second member 20 together with the third member 40. This different point will be mainly described in the present embodiment.

The fastening member 80 fastens and fixes the third member 40 to the second member 20 and maintaining a pressurized state of the connection member 30 by the first member 10 and the second member 20. The fastening member 80 has, for example, a base portion 81 and a screw 82. The base portion 81 has a planar size larger than that of the third member 40 and abutting on a surface opposite to a surface from which the first member 10 is exposed. The screw 82 is inserted into a screw hole formed in the base portion 81. The fastening member 80 is fixed to the second member 20 in a state where the base portion 81 presses the first member 10 together with the third member 40 by inserting the screw 82 into the screw hole 25 of the second member 20. Accordingly, the pressurized state of the connection member 30 is maintained, and the contact state between the first member 10 and the second member 20 and the carbon material 32 can be favorably maintained. That is, the fastening member 80 functions as a pressing member relative to the connection member 30 supported between the first member 10 and the second member 20. For example, the screw hole is formed in a part of the base portion 81 not overlapping with the third member 40.

The present embodiment also provides a connection structure with the same effects as those of the first embodiment. The connection structure of the present embodiment also provides the following effects.

(1) Since the fastening member 80 is provided, the first member 10 is fixed to the second member 20, and a state in which the connection member 30 is pressed is maintained. Therefore, in this connection structure, an effect of further stabilizing a contact state between the carbon material 32 and the first member 10 and the second member 20 can be obtained.

### Modification of Sixth Embodiment

For example, as shown in FIG. 28, in the connection structure of the sixth embodiment, the fastening member 80 may be constituted only by the screw 82. The screw 82 penetrates the third member 40, and the second member 20 and the third member 40 are screwed to each other.

For example, as illustrated in FIG. 29, the connection structure of the sixth embodiment includes a pressing member 90 that pressurizes the first member 10 together with the third member 40 instead of the fastening member 80. The pressing member 90 includes, for example, a plate member 91, a facing member 92 and an elastic body 93. The plate member 91 is in contact with the third member 40. The facing member 92 is disposed to face the plate member 91. The elastic body 93 is disposed between the plate member 91 and the facing member 92. For example, the pressing member 90 is disposed between the plate member 91 and the facing member 92 in a state where the elastic body 93 is contracted, and is configured to press the plate member 91 by a restoring force. The facing member 92 is, for example, any member that is fixed in any way, and is configured not to be deformed by the restoring force of the elastic body 93. Even in such a configuration, the connection member 30 is maintained in a state of being pressed by the first member 10 and the second member 20 together with the third member 40. The pressing member 90 may be made of a resin material, a metal material, a composite material thereof, or any other material.

The modification also provides a connection structure capable of obtaining the same effects as those of the sixth embodiment.

### Other Embodiments

Although the present disclosure has been described in accordance with the embodiments, it is understood that the present disclosure is not limited to such embodiments or structures. The present disclosure also includes various modifications and modifications within an equivalent range. In addition, various combinations and modes, and further, other combinations and modes including one element of these alone, or thereabove, or therebelow, are also comprised within the scope or concept range of the present disclosure.

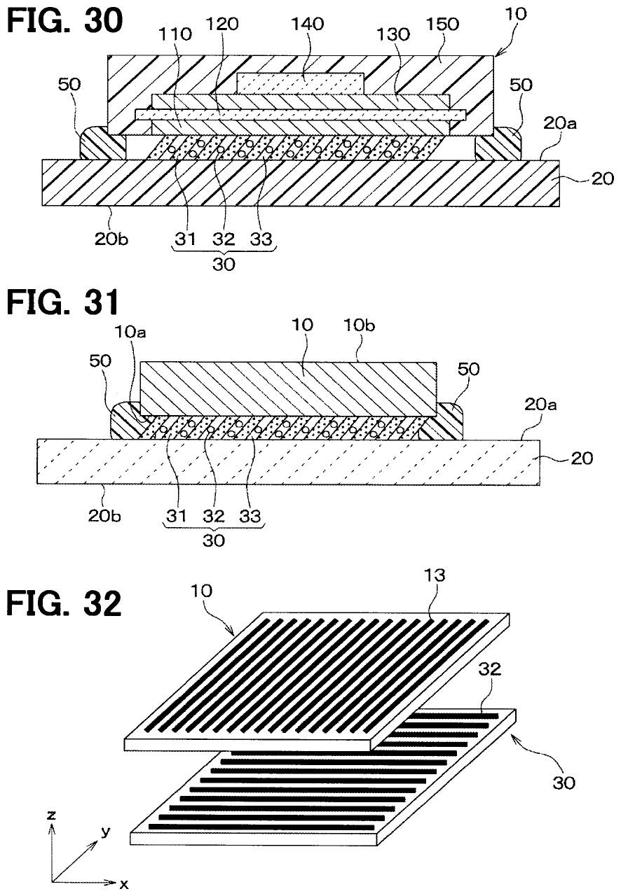

(1) As illustrated in FIG. 30, the first member 10 may be a semiconductor module. For example, the semiconductor module includes a semiconductor element 140, a stacked body of the heat dissipation plate 110, the insulating substrate 120, and the metal layer 130, and a mold resin 150 that covers the semiconductor element 140 and a part of the stacked body. For example, the semiconductor element 140 is joined to the metal layer 130 by solder (not illustrated) and the heat dissipation plate 110 is exposed from the mold resin 150. The semiconductor element 140 is, for example, a heating element such as a metal oxide semiconductor field effect transistor (MOSFET) or an insulated gate bipolar transistor (IGBT), and a wire, a metal clip, or the like, which is not illustrated, is connected thereto. In the semiconductor module, the heat dissipation plate 110 is thermally connected to the connection member 30. In this case, for example, the second member 20 is a radiator such as a cooler made of Al or the like. FIG. 30 illustrates an example in which the connection structure of the fourth embodiment is a semiconductor device in which a semiconductor element and a cooler are connected via the connection member 30, but other embodiments can also be applied to a semiconductor device.

(2) As shown in FIG. 31, in the connection structure of the fourth embodiment, the first member 10 is a conductive layer such as a metal plate or a graphite heat dissipation plate, and the second member 20 is a ceramic substrate, so as to constitute an insulation built-in substrate. In this case, the main thermal connection between the first member 10 and the second member 20 is defined by the connection member 30, and the bonded region is defined only the sealing member 50. Therefore, even if the thickness of the first member 10 is increased, the influence of stress is reduced. In addition, the insulation built-in substrate to which this connection structure is applied has a smaller bonding region and a reduced stress, compared with a conventional configuration in which most of the conductive layer and the insulating layer are connected by a brazing material. Accordingly, it is possible to obtain a high degree of freedom in design. When the first member 10 is a graphite heat dissipation plate, as illustrated in FIG. 32, the connection member 30 is preferably arranged such that the heat conduction direction in the plane of the connection member 30 intersects the heat conduction direction in the plane of the first member 10 which is a graphite heat dissipation plate. For example, in FIG. 32, the horizontal direction of the paper surface is defined as an x direction, the direction orthogonal to the x direction is defined as a y direction, and the direction orthogonal to the xy plane is defined as a z direction. When the first member 10 has a configuration in which the graphites 13 extend along the y direction and are arranged in parallel in the x direction, the heat conduction direction thereof is the y direction. In the first member 10, the heat conduction direction in the xy plane is the y direction. In such a case, for example, the connection member 30 is preferably arranged such that the carbon material 32 extends in the x direction, that is, the heat conduction direction in the xy plane is the x direction. Accordingly, the efficiency of heat conduction in the xy plane is further improved.

The constituent element(s) of each of the above embodiments is/are not necessarily essential unless it is specifically stated that the constituent element(s) is/are essential in the above embodiment, or unless the constituent element(s) is/are obviously essential in principle. A quantity, a value, an amount, a range, or the like referred to in the description of the embodiments described above is not necessarily limited to such a specific value, amount, range or the like unless it is specifically described as essential or understood as being essential in principle. In each of the above embodiments, when the shape, positional relationship, and the like of the constituent elements and the like are referred to, the shape, the positional relationship, and the like are not limited unless otherwise specified or limited to specific shapes, positional relationships, and the like in principle.

What is claimed is:

1. A connection structure comprising:
a first member;
a second member arranged to oppose the first member and made of a material having a coefficient of linear expansion different from that of the first member;
a connection member that connects the first member and the second member with each other, wherein
the connection member includes
a heat-resistant resin material,
a carbon material made of carbon atom, and
a void layer.

2. The connection structure according to claim 1, wherein
the carbon material has one end in contact with the first member, and the other end, which is opposite to the one end, in contact with the second member.

3. The connection structure according to claim 2, wherein
the carbon material defines a heat conduction direction connecting the first member and the second member with each other, and
an angle between a thickness direction of the connection member and the heat conduction direction of the carbon material is within a range more than or equal to 14° and less than or equal to 70°.

4. The connection structure according to claim 2, wherein
a contact surface of the first member or/and the second member in contact with the carbon material has a recess that increases a frictional force relative to the carbon material.

5. The connection structure according to claim 2, further comprising: an organic film on a contact surface of the first member or/and the second member in contact with the carbon material so as to be bonded to the carbon material.

6. The connection structure according to claim 5, wherein the organic film is made of an organic material having a triazine ring.

7. The connection structure according to claim 2, further comprising:
a third member surrounding an outer peripheral portion of the first member and arranged to face the second member; and
a sealing member having a frame shape that surrounds an outer peripheral portion of the connection member, the sealing member connecting the second member and the third member.

8. The connection structure according to claim 7, wherein
an internal space is defined and surrounded by the second member, the third member, and the sealing member, and
at least one of the second member and the third member has a communication portion that communicates the internal space with an external space.

9. The connection structure according to claim 2, further comprising:
a third member surrounding an outer peripheral portion of the first member and arranged to face the second member; and
a sealing member surrounding an outer peripheral portion of the connection member and connecting the second member and the third member, wherein
an internal space is located between the second member and the third member, and
the sealing member is disposed so as to form a gap serving as a communication portion that communicates the internal space with an external space.

10. The connection structure according to claim 7, wherein
at least one of the second member and the third member includes a high adhesion portion having a recess into which a part of the sealing member is filled, and
the high adhesion portion has a tight contact with the sealing member higher than the other portion of the second member and the third member.

11. The connection structure according to claim 2, wherein
a portion of the carbon material in contact with the first member and a portion of the carbon material in contact with the second member are chemically modified, and
the carbon material is chemically bonded to the first member and the second member.

12. The connection structure according to claim 2, further comprising a pressing member configured to press the connection member against one of the first member and the second member via the other of the first member and the second member.

13. A semiconductor device comprising:
a semiconductor module having a semiconductor element and a heat dissipation plate thermally connected to the semiconductor element;
a radiator arranged to oppose the heat dissipation plate of the semiconductor module; and
a connection member that connects the semiconductor module and the radiator with each other, wherein
the connection member includes a heat-resistant resin material, a carbon material made of carbon atom, and a void layer.

14. An insulation substrate comprising:
a conductive layer made of a conductive material;
an insulating layer arranged to oppose the conductive layer and made of an insulating material; and
a connection member that connects the conductive layer and the insulating layer with each other, wherein
the connection member includes a heat-resistant resin material, a carbon material made of carbon atom, and a void layer.
